(19) United States
(12) Patent Application Publication
(10) Pub. No.: US 2015/0301977 A1
(43) Pub. Date: Oct. 22, 2015

(54) Distributed Termination for Flyby Memory Buses

(71) Applicant: William Michael Gervasi, (US)

(72) Inventor: William Michael Gervasi, Ladera Ranch, CA (US)

(21) Appl. No.: 14/691,118

(22) Filed: Apr. 20, 2015

Related U.S. Application Data
(60) Provisional application No. 61/982,102, filed on Apr. 21, 2014.

(51) Int. Cl. G06F 13/42; G11C 7/10; G06F 13/16

(52) U.S. Cl. CPC G06F 13/4234; G06F 13/1663; G11C 7/1072

(57) ABSTRACT

Methods and systems that perform distributed termination for shared signal buses on memory modules. Distributed termination improves signal quality and results in higher overall memory performance. Distributed termination enables depopulation of devices on branches without significant performance degradation. Distributed termination enables new signal topologies that may enable higher performance.

### PRIORITY CLAIM

This application claims the benefit of U.S. Provisional Application Ser. No. 61/982,102, filed Apr. 21, 2014, the contents of which are hereby incorporated by reference.

### FIELD OF THE INVENTION

The invention concerns improvements for flyby communication buses on memory modules in memory subsystems, improving signal quality and thereby increasing performance.

### BACKGROUND OF THE INVENTION

Computer memory module designs in recent years adopted a signaling scheme referred to as “flyby” for collections of shared signals including addresses, commands, controls, and clocks used to interface to memory devices such as DRAMs. In a flyby bus, a signal connects from a source point, such as the finger at the edge of a memory module, to a first DRAM, then travels to a second DRAM, then a third and so on until the end of the memory bus is reached. To prevent reflected energy from the end of the flyby bus from bouncing back and disrupting signal quality to the devices on the bus, a resistive element is connected from the signal to a termination voltage, often called VTT.

Also common on the flyby bus is the desire to connect two DRAMs to the same branch point on the bus, such as a DRAM on the front of the module and another DRAM on the back of the module. These configurations are called “ranks” where the DRAMs on one side of the module collectively are called “rank 0” while the DRAMs on the other side of the module are collectively called “rank 1”.

Connecting the signal to the DRAM in rank 0 and its associated DRAM in rank 1 (i.e., when they are connected to the same data signals) requires shorter wires that branch off the main flyby bus called “stubs”. These stubs affect signal quality when they are left unterminated.

Typically, the industry must provide two different module designs, a “one rank” module with only one DRAM connection “stub” from each branch point to the appropriate DRAM input, and a separate “two rank” design with two stubs from each branch point, one for each rank. Depopulating a two rank module by only installing rank 0, for example, leaves unterminated stubs on the wires to where the rank 1 DRAMs would normally be mounted, causing undesirable reflected noise.

A variation of the flyby bus commonly used is a branched topology where two or more flyby buses are joined at a source signal point and each flyby bus is separately terminated.

Commonly used module variations include 64-databit wide modules and similar 72-databit wide modules with an added error correction code (ECC) device. At high frequencies, a 72-databit module cannot be depopulated to create a 64-databit module due to reflected noise from the depopulated DRAM location, requiring distinct designs for 64 and 72 data bit variations.

The flyby bus as implemented in current generation memory modules is partially limited in performance range by inherent asymmetry of the signals that reach the DRAMs sharing the bus. The single termination resistive element at the end of the bus cannot completely counter the effects of the stubs to each of the DRAM inputs. Each stub reflects some amount of energy back onto the bus, even with a DRAM installed on that stub and worse when any stub is left open and unterminated or unloaded. Along with pattern dependency from the unpredictable data sets which may be broadcast on the bus, this creates a nearly infinite number of permutations of noise on the bus which decrease the available data valid window, or “eye”. Because each DRAM has a unique location on the flyby bus, these permutations of signal noise are unique to each location, therefore each DRAM has a different set of problems. The overall performance of the module is determined by the weakest link.

### SUMMARY OF THE INVENTION

An embodiment of the present invention provides a flyby bus with distributed termination, which reduces the effects of signal reflections on the flyby bus by increasing the number of termination points along the bus. In one implementation of the invention, a termination resistive element to termination voltage (VTT) is located at the end of every signal stub on the bus of shared signals.

Distributed termination reduces or nearly eliminates reflected energy, dramatically reducing the permutations of reflected energy patterns on the bus. This also reduces the variation of signal quality at each DRAM location, sensitivity to data patterns and other unwanted effects of excessive stubs in the traditional flyby buses, raising the overall module performance. Distributed termination normalizes signal quality for each location compared to traditional flyby split buses.

Terminating all stubs on a two rank design also allows depopulating one of the ranks without severely affecting the overall bus signal quality. This enables a single memory module design that can support 1 rank or 2 ranks using the same printed circuit board. Terminating all stubs also allows for a 72-databit memory module design to be depopulated to create a 64-databit version without significantly degrading module performance or incurring the reflection penalties from unpopulated DRAM sites.

The routing pattern is entered in the middle or any other place in the flyby bus, thus reducing the skews between the timing of DRAMs on the bus since signal paths are shortened.

An alternative to distributed termination at each DRAM, due to layout restrictions or other practical factors, is termination at branch points to multiple DRAMs.

In one embodiment, termination values are chosen for Thevenin equivalence, such as 39 ohms Other Thevenin values may be selected based on simulation or experimentation.

Other device types using flyby signaling interconnection including but not limited to Flash, SRAM, CPUs, etc. may also implement distributed termination.

Motherboard or other applications of the flyby signaling topology may also implement distributed termination methods and configurations.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 shows a block diagram of a motherboard of a typical computer system with a memory controller and three optional memory slots into which memory modules may be inserted;

FIG. 2 shows a block diagram of a typical unbuffered memory module;

FIG. 3 shows a block diagram of a typical registered memory module;

FIG. 4 illustrates details about terminated flyby signals used on unbuffered memory modules;

FIGS. 5a-c show variations of signals on unbuffered memory module configurations and the results of depopulating a DRAM location;

FIG. 6 shows split flyby signaling used on registered memory modules;

FIG. 7 shows the use of fixed value distributed termination on a flyby signal path;

FIG. 8 shows the use of fixed value distributed termination on a split flyby signal path;

FIGS. 9a-b show the use of distributed termination to allow depopulation of a memory module DRAM location without affecting signal quality;

FIG. 10 shows fixed value distributed termination where a flyby signal path is replaced with a split signal path;

FIG. 11 shows a distributed terminated signal path with termination eliminated at some stub locations on the signal paths;

FIG. 12 shows a flyby signal path with distributed termination where the resistor value of each terminator may be unique; and

FIG. 13 shows a flyby signal path with distributed termination at branch points instead of at the end of each stub.

### DETAILED DESCRIPTION OF THE DRAWINGS

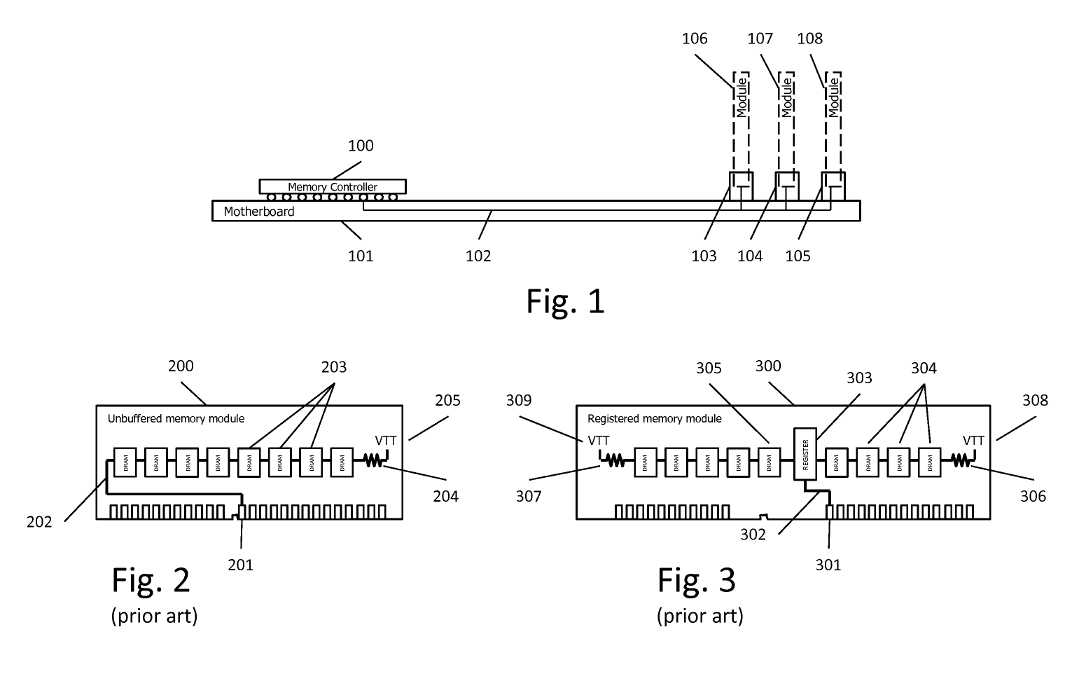

FIG. 1 shows a block diagram of a typical computer system with a memory controller 100, often incorporated inside a CPU, connected via wires or traces 102 on a motherboard 101 to multiple sockets 103, 104, 105. Each socket is optionally populated with a memory module 106, 107, 108.

FIG. 2 shows a simplified block diagram of one type of memory module that is used in current generation computer systems. An unbuffered memory module 200 connects the shared signals such as address signals from the dynamic random access memories (DRAMs) directly to the edge connector 201 using a flyby connection 202 from one DRAM 203 to the next. A fly-by topology daisy chains the address and control lines through a single path across each DRAM. A termination resistive element 204 is connected at the end of the line to a termination voltage such as VTT 205.

FIG. 3 shows a simplified block diagram of a second type of commonly used module called a registered memory module 300 where there is a buffering device called a register 303 that retransmits shared signals 302 such as addresses from an edge connector 301 to multiple groups of DRAMs 304, 305 using flyby signaling to each group in flyby busses. Each flyby bus is terminated with resistive elements 306, 307 to a termination voltage such as VTT 308, 309.

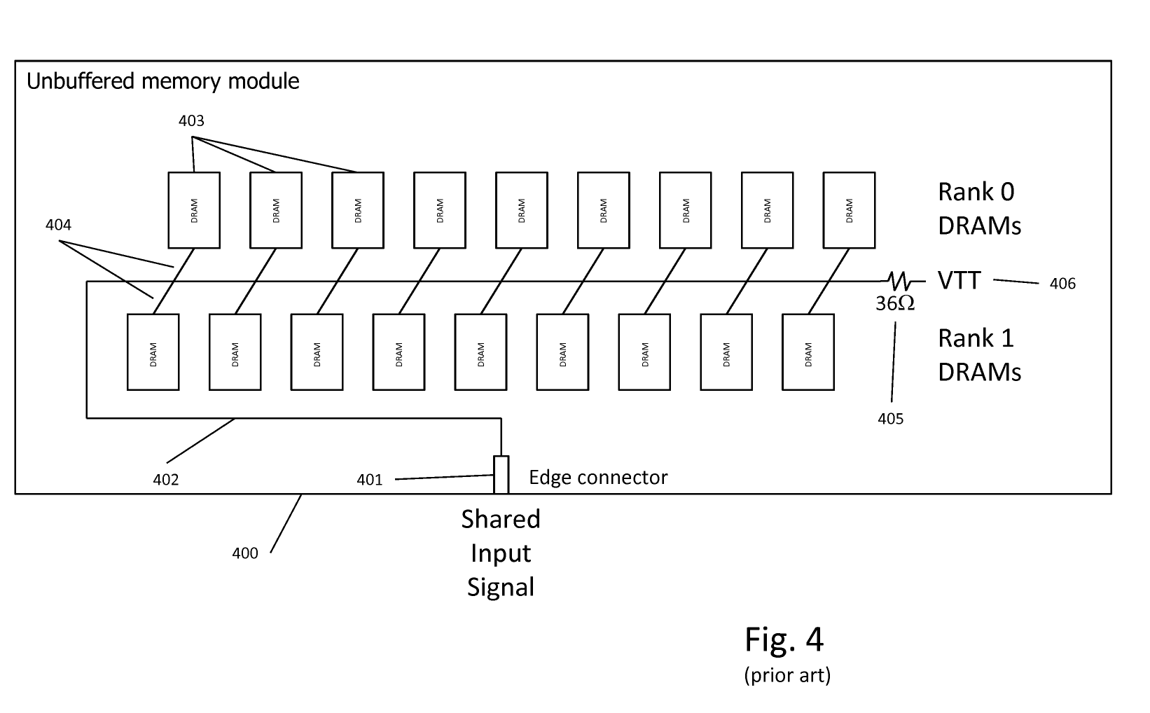

FIG. 4 shows a block diagram of a current generation two rank memory module 400 such as an unbuffered dual inline memory module (UDIMM). A shared signal typical of an address bit, command bit, or control signal is shown entering the module 400 at an edge connector 401, routed via a wire/trace 402 to the leftmost DRAM pair with rank 0 at the top and rank 1 at the bottom (in actual implementations, typically front and back sides of a printed circuit board). Stubs 404 from the shared bus signal branch to rank 0 and 1 as the signal proceeds from left to right, and a single termination resistive element 405 of 36 ohms is connected from the shared signal to a termination voltage (VTT) 406.

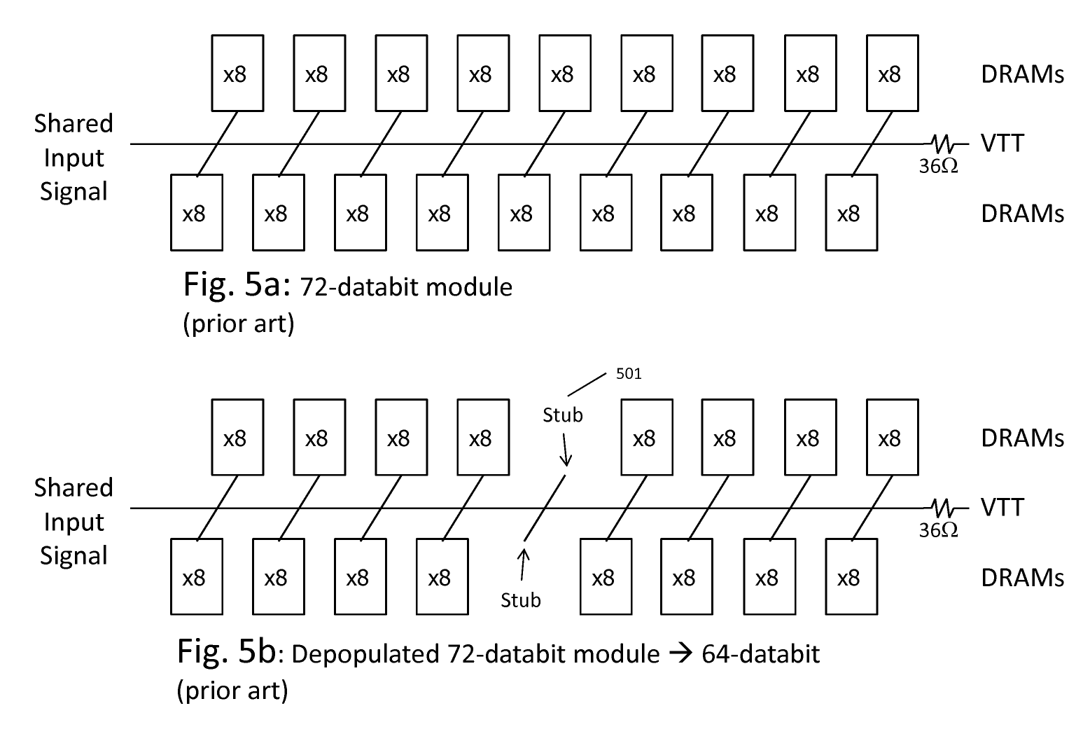

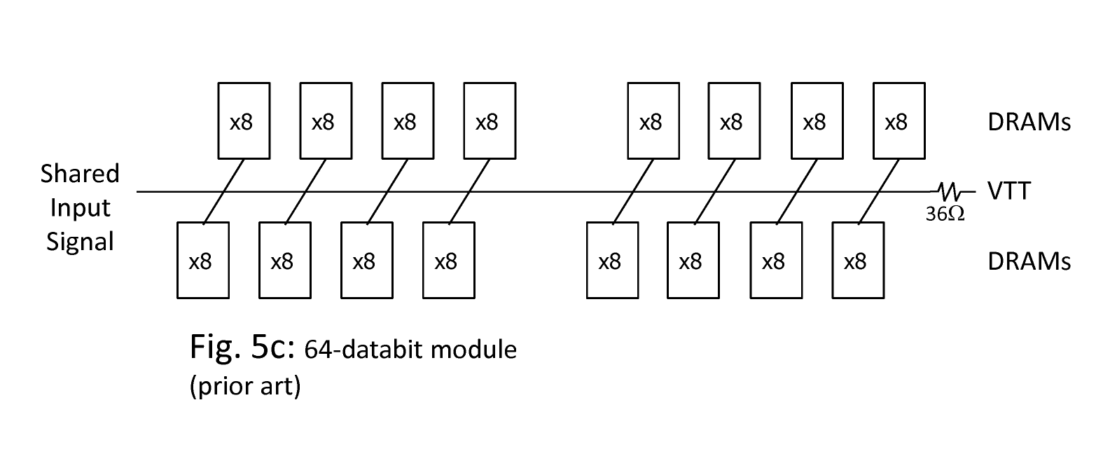

FIGS. 5a-c show block diagrams of current generation UDIMM designs, one for 72-databit configuration (FIG. 5a) and one for 64-databit configuration (FIG. 5c) constructed using DRAMs with eight data bits each (x8). Using the 72-databit variation with the middle (ECC) devices depopulated as shown in FIG. 5b would leave unloaded stubs 501 at those locations, degrading signal quality, so this is seldom done for high frequency modules.

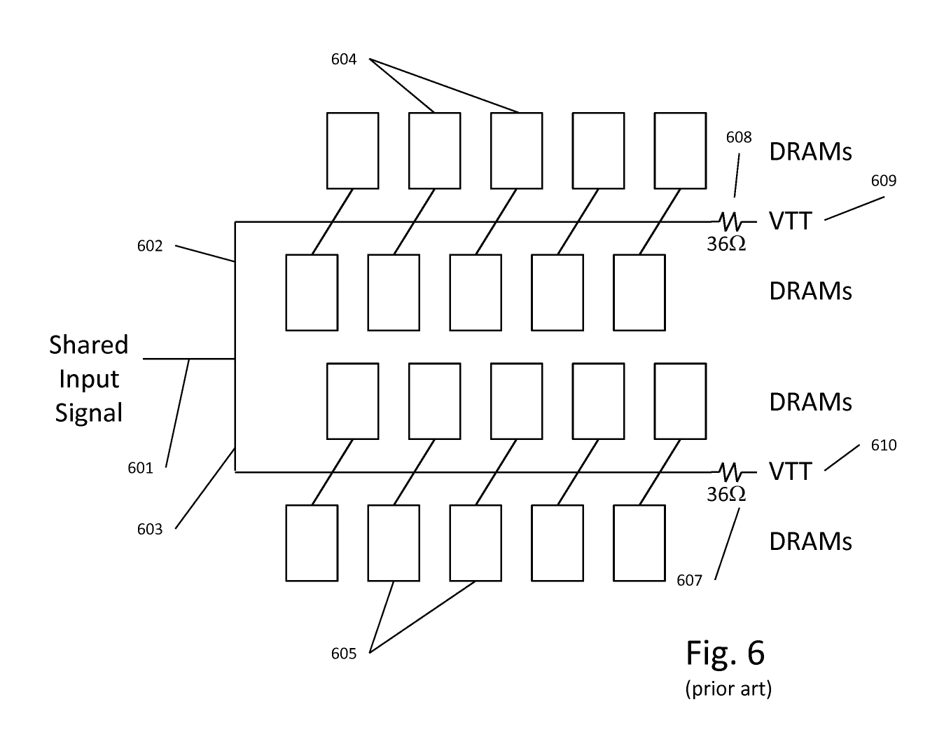

FIG. 6 shows a block diagram of a current generation split flyby buses as often implemented on registered dual inline memory modules (RDIMMs) or load reduced dual inline memory modules (LRDIMMs). A shared signal 601 branches into two flyby buses 602, 603, with a collection of memory devices 604, 605 on each. Each flyby bus is separately terminated with a resistive element 607, 608 to VTT 609, 610.

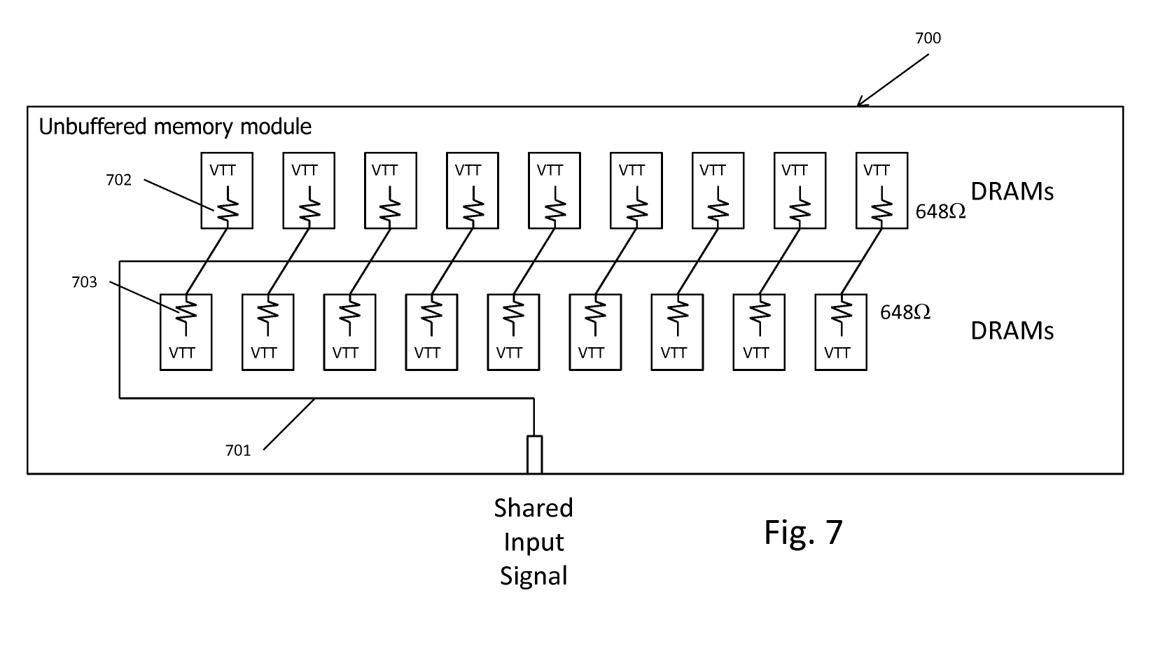

FIG. 7 shows a block diagram of one embodiment of a memory module 700 with termination resistive elements 702, 703 distributed at the end of every stub on a flyby bus 701. These resistive elements 702, 703 are located as close to the input signal at each DRAM as practical implementation allows, and ideally at the physical end of the stub trace where it connects to the terminal of the DRAM. The stub traces from the flyby bus wire to the terminals of the DRAM also have a connection to one terminal of a termination resistor, and the other terminal of the resistor is tied to terminal voltage VTT. Using embedded resistor technology, for example, these resistive elements could physically be located in the printed circuit board of the memory module (e.g., 106-108) below the package of the DRAM, or in the DRAM substrate itself. The shared signal enters the module at the bottom center as with the current generation UDIMMs, but each stub along the flyby is terminated individually, and termination at the end of the line is eliminated relative to the current generation flyby bus. An example distributed termination value of 648 ohms is used for each of the resistive elements 702, 703. When 648 ohms is divided by the number of resistive elements (18 in this example), a Thevenin equivalent of the 36 ohms, similar to that used in current UDIMMs, is the result, thereby enhancing compatibility with current generation implementations. Other resistor values may be used in order to produce different Thevenin equivalents.

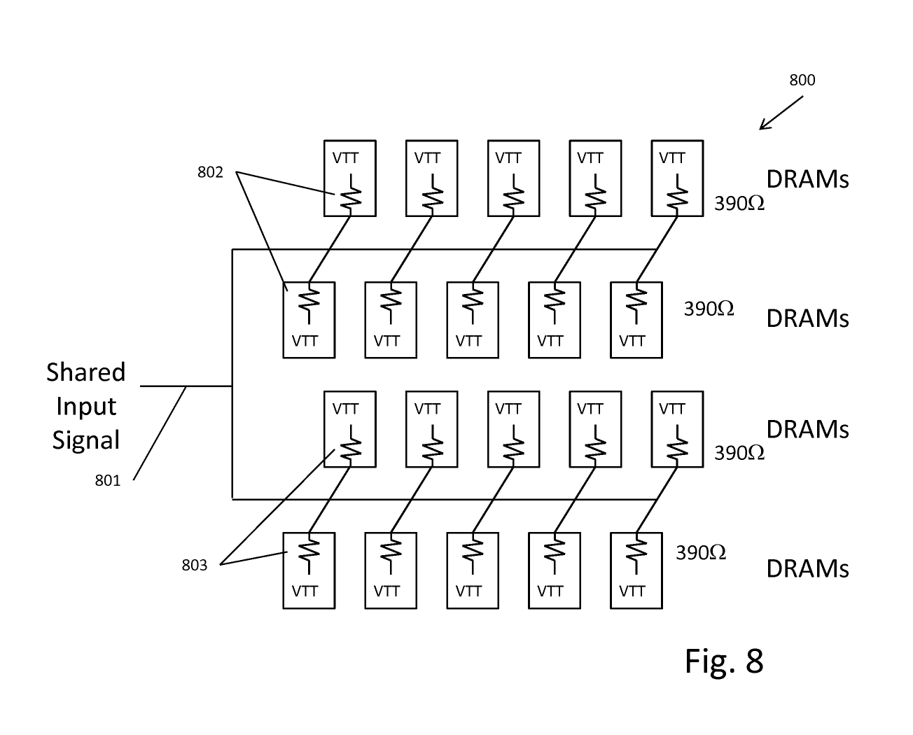

FIG. 8 shows a memory module 800 that uses distributed termination with split flyby buses. In this example, distributed termination values of 390 ohms are used for the ten resistive elements on each split flyby bus 801. This provides a Thevenin equivalent of the 39 ohm termination similar to that used on each branch of the current generation RDIMM or LRDIMM.

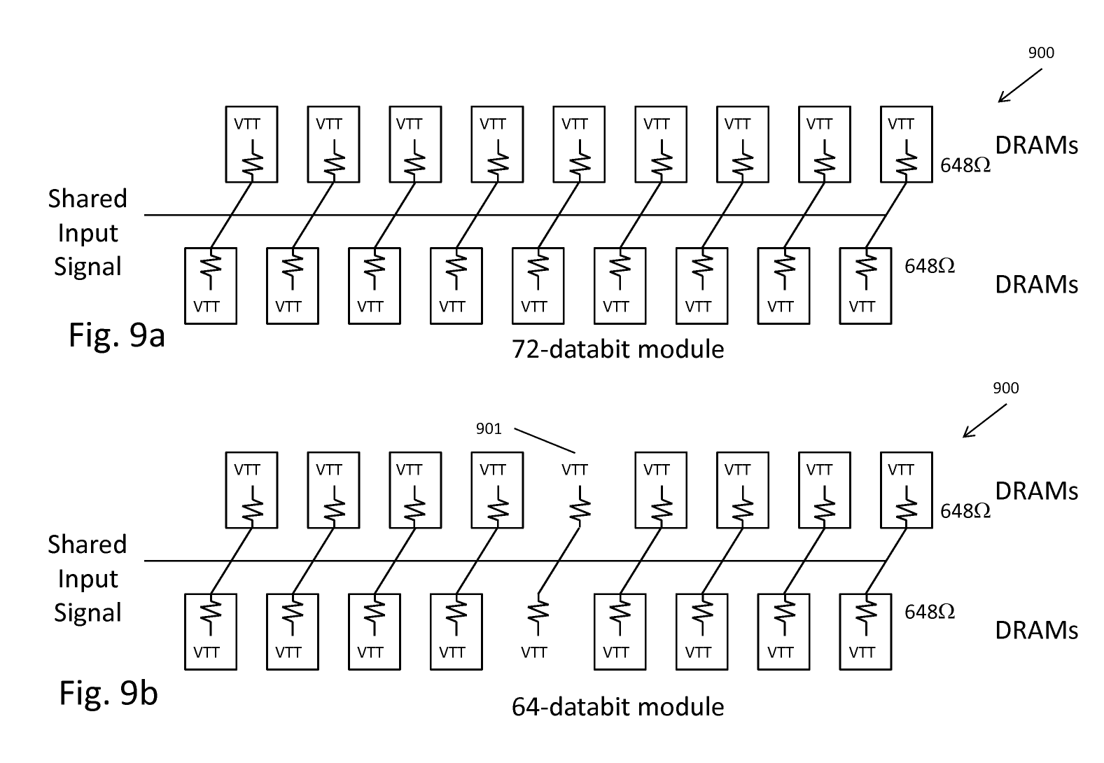

FIG. 9a shows a memory module 900 that includes a distributed termination configured as a two rank 72-databit module. FIG. 9b shows the memory module 900 after a pair of DRAMs 901 have been depopulated (i.e., DRAM devices omitted during assembly without changing the board design) to create a two rank 64-databit memory module without significantly disrupting signal quality since every stub from the bus is terminated, including the depopulated DRAM location.

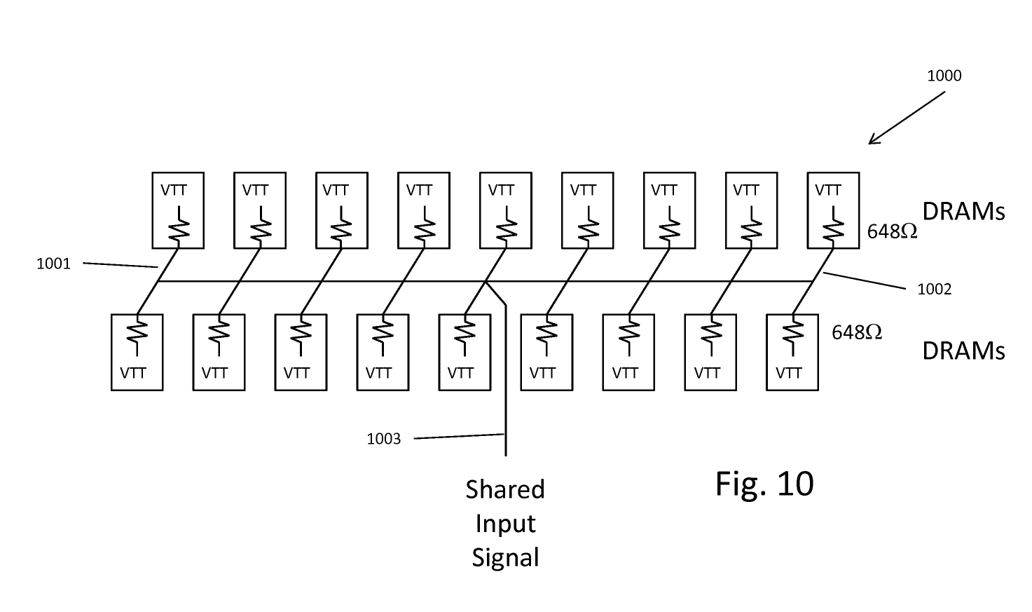

FIG. 10 shows a memory module 1000 of a variant of memory module 900. A shared signal 1003 is brought from an edge connector (not shown) at the bottom to a point between a left and a right flyby bus 1001, 1002, splitting it into two. This reduces the length of the flyby bus and reduces skew between nearest and farthest memory on the flyby chain.

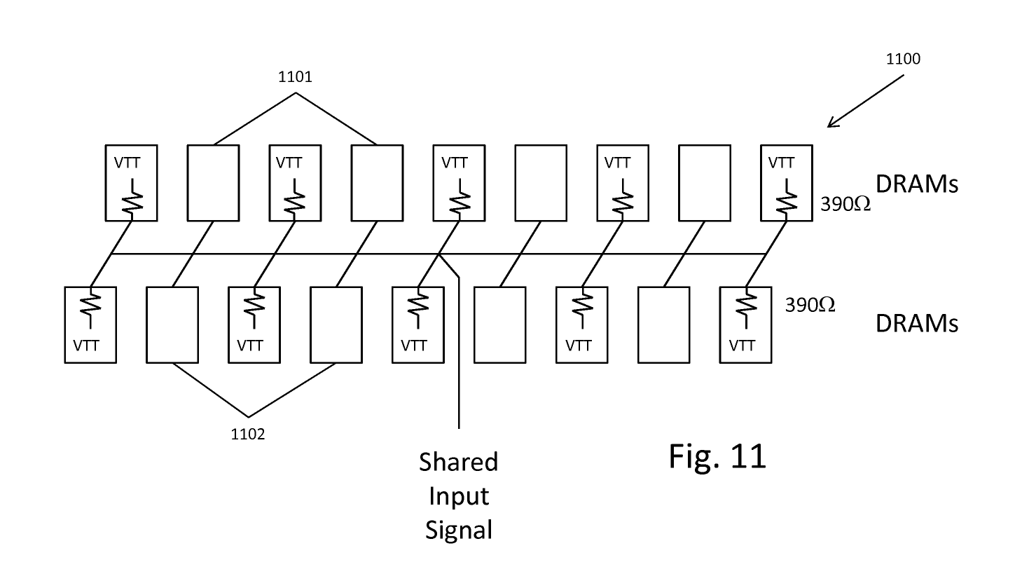

FIG. 11 shows a memory module 1100 of a sparsely terminated version compared to memory module 1000 of FIG. 10. Some DRAM pairs 1101, 1102 are left without a termination. This variation may be chosen due to constraints on space on the memory module to fit all the resistive elements for all the DRAM pairs. Termination resistor values are chosen in order to provide a desired Thevenin equivalent termination.

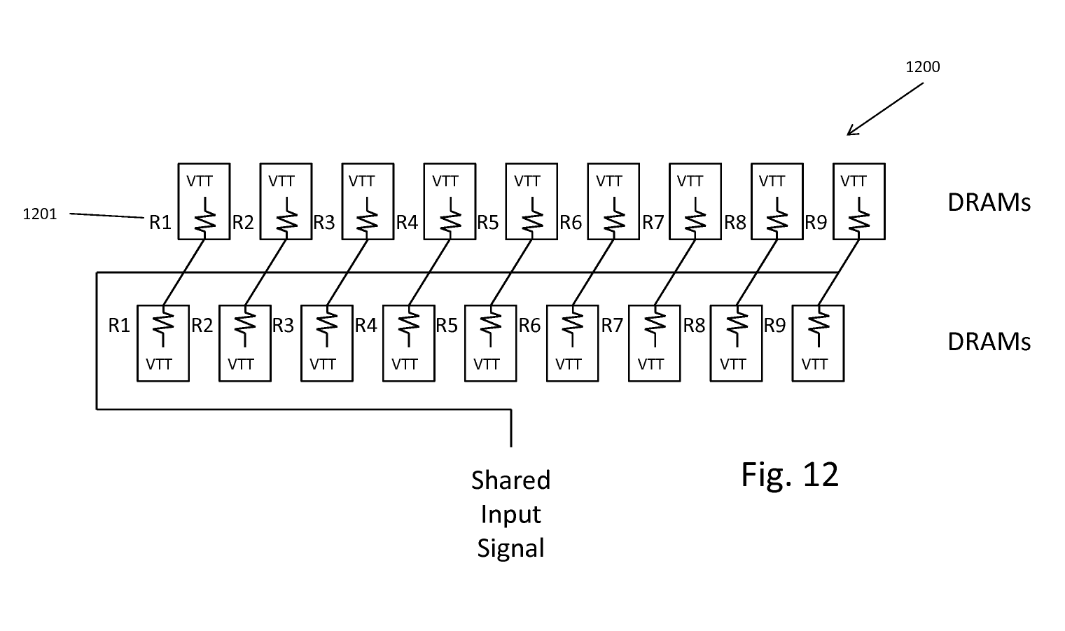

FIG. 12 shows a memory module 1200 of a further refinement of distributed termination. Instead of using a fixed value such as 648 ohms, each resistive element R1 through R9 1201 may have different values based on the optimal requirements for signal quality at that location on the flyby bus. For example, resistors R1 and R9 may have higher resistance and R5 a lower resistance based on the resulting signal quality at the terminals of the associated DRAMs. Similarly, resistors R2-R4 and R6-R8 may have distinct values based on signal requirements.

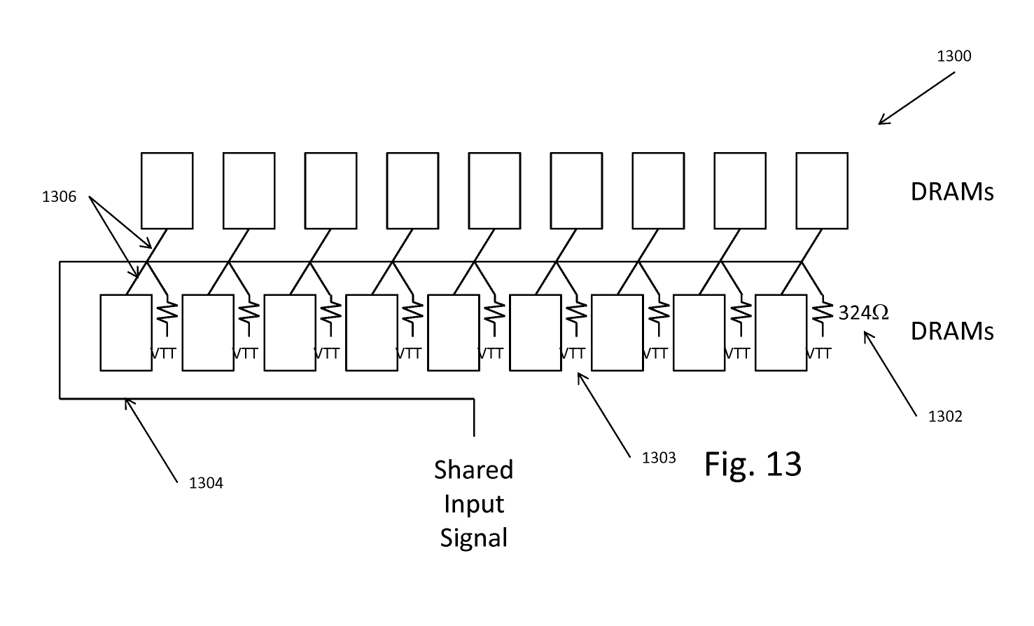

FIG. 13 shows a memory module 1300 of a sparsely terminated version compared to the memory module 1200 of FIG. 12. In this variation, termination resistive elements 1302 to termination voltage VTT 1303 are located on the module board at or near the branch points from the main flyby signal path 1304 to the stubs 1306 that connect to the DRAM inputs. This variation may be chosen due to constraints on space on the module to fit all the resistive elements for all the DRAM pairs. Termination resistor values are chosen in order to provide a desired Thevenin equivalent termination.

Any of the examples shown here may use different Thevenin equivalent terminations than the standard line-end values in order to achieve improved signal quality.

While the preferred embodiment of the invention has been illustrated and described, it will be appreciated that various changes can be made therein without departing from the spirit and scope of the invention.

What is claimed is:

1. A computer memory module comprising:
a shared input configured to receive an input signal;
a bus connected to the shared input; and
a plurality of memory devices connected via stubs to the bus, wherein the plurality of memory devices are configured to allow the input signal to propagate through the memory devices,
wherein each of at least a portion of the memory devices comprise:
a resistive element having a first end connected to the stub; and
a second end connected to a termination voltage.

2. The computer memory module of claim 1, wherein the values of the resistive elements are based at least on a desired signal quality.

3. The computer memory module of claim 1, wherein the values of the resistive elements are based at least on a desired Thevenin equivalent.

4. The computer memory module of claim 1, wherein the values of the resistive elements vary depending on the location where the shared input is received on the bus.

5. The computer memory module of claim 1, wherein the plurality of memory devices are attached to the bus using a split flyby topology.

6. The computer memory module of claim 5, wherein the plurality of memory devices are attached to the bus using a flyby topology, the plurality of memory devices are attached in pairs to the bus.

7. The computer memory module of claim 6, wherein the plurality of memory devices comprise dynamic random access memory (DRAM) devices.

8. The computer memory module of claim 1, wherein the resistive elements are equivalent in all of the memory devices.

9. The computer memory module of claim 1, wherein at least two of the resistive elements are not equivalent.

10. The computer memory module of claim 1, wherein the first end of the resistive element is connected to a point where the stub and the bus meet.

11. A computer circuit comprising:
a circuit board;
a memory controller connected to the circuit board;
one or more memory module sockets connected to the circuit board and electrically connected to the memory controller; and
one or more memory modules, each of the memory modules configured to be received one of the memory module sockets, each of the memory modules comprising:
a shared input configured to receive an input signal;
a bus connected to the shared input; and
a plurality of memory devices connected via stubs to the bus, wherein the plurality of memory devices are configured to allow the input signal to propagate through the memory devices,
wherein each of at least a portion of the memory devices comprise:
a resistive element having a first end connected to the stub; and
a second end connected to a termination voltage.

12. The circuit of claim 11, wherein the values of the resistive elements are based at least on a desired signal quality.

13. The circuit of claim 11, wherein the values of the resistive elements are based at least on a desired Thevenin equivalent.

14. The circuit of claim 11, wherein the values of the resistive elements vary depending on the location where the shared input is received on the bus.

15. The circuit of claim 11, wherein the plurality of memory devices are attached to the bus using a split flyby topology.

16. The circuit of claim 15, wherein the plurality of memory devices are attached to the bus using a flyby topology, the plurality of memory devices are attached in pairs to the bus.

17. The circuit of claim 16, wherein the plurality of memory devices comprise dynamic random access memory (DRAM) devices.

18. The circuit of claim 11, wherein the resistive elements are equivalent in all of the memory devices.

19. The circuit of claim 11, wherein at least two of the resistive elements are not equivalent.

20. The circuit of claim 11, wherein the first end of the resistive element is connected to a point where the stub and the bus meet.
